(19) United States
(12) Patent Application Publication
(10) Pub. No.: US 2025/0266404 A1
(43) Pub. Date: Aug. 21, 2025

(54) DISPLAY DEVICE

(71) Applicant: LG Display Co., Ltd., Seoul (KR)

(72) Inventors: Hyun-Min PARK, Paju-si (KR); Da-Yeon JEONG, Paju-si (KR)

(73) Assignee: LG Display Co., Ltd., Seoul (KR)

(21) Appl. No.: 18/916,366

(22) Filed: Oct. 15, 2024

(30) Foreign Application Priority Data
Feb. 20, 2024 (KR) 10-2024-0024288

(51) Int. Cl. H01L 25/075; H01L 33/56

(52) U.S. Cl. CPC H01L 25/0753; H10H 20/854; H10H 20/032; H10H 20/0362

(57) ABSTRACT

A display device includes: a substrate having a plurality of subpixels; a transistor in each of the plurality of subpixels; a first bank layer surrounding the plurality of subpixels; an auxiliary electrode on the first bank layer; a light emitting diode in each of the plurality of subpixels, the light emitting diode including a first electrode, an emitting layer on the first electrode and a second electrode on the emitting layer; and a first encapsulating layer on the light emitting diode in each of the plurality of subpixels, wherein the auxiliary electrode and the first bank layer have an undercut shape, and wherein the second electrode contacts the auxiliary electrode such that the second electrodes of adjacent two of the plurality of subpixels are electrically connected to each other.

### CROSS REFERENCE TO RELATED APPLICATIONS

The present application claims the benefit of the priority to Republic of Korea Patent Application No. 10-2024-0024288 filed in Republic of Korea on Feb. 20, 2024, which is hereby incorporated by reference herein in its entirety.

### BACKGROUND

### Technical Field

The present disclosure relates to a display device, and more particularly, to a display device where a lateral leakage current is prevented.

### Description of the Related Art

Recently, as a multimedia is progressed, an importance of a display device increases. As a result, a flat panel display such as a liquid crystal display (LCD), a plasma display panel (PDP) and a micro light emitting diode (LED) display having a small size and a thin profile has been suggested. The flat panel display may be applied to various electronic equipment such as a smart phone and a tablet PC.

The display device includes various layers and various elements such as a display unit displaying an image as well as various electrodes. When a moisture permeates into the display device from an exterior, the electrodes is corroded or the organic layer is deteriorated.

To fabricate the display device having a relatively high resolution, a gap between subpixels is required to be minimized. However, as the gap is reduced, a lateral leakage current between the adjacent subpixels is generated. The lateral leakage current causes an undesirable emission in a pixel such that the display device is deteriorated.

### SUMMARY

Accordingly, the present disclosure is directed to a display device that substantially obviates one or more of the problems due to limitations and disadvantages of the related art.

An object of the present disclosure is to provide a display device where a lateral leakage current between adjacent subpixels is prevented by an organic layer is cut between the adjacent subpixels.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the objects of the present disclosure, as embodied and broadly described herein, a display device includes: a substrate having a plurality of subpixels; a transistor in each of the plurality of subpixels; a first bank layer surrounding the plurality of subpixels; an auxiliary electrode on the first bank layer; a light emitting diode in each of the plurality of subpixels, the light emitting diode including a first electrode, an emitting layer on the first electrode and a second electrode on the emitting layer; and a first encapsulating layer on the light emitting diode in each of the plurality of subpixels, wherein the auxiliary electrode and the first bank layer have an undercut shape, and wherein the second electrode contacts the auxiliary electrode such that the second electrodes of adjacent two of the plurality of subpixels are electrically connected to each other.

In another aspect, a display device includes: a substrate having a plurality of subpixels; a bank layer surrounding the plurality of subpixels; a light emitting diode in each of the plurality of subpixels, the light emitting diode including a first electrode, an emitting layer on the first electrode and a second electrode on the emitting layer; a first encapsulating layer in each of the plurality of subpixels; and an auxiliary electrode between adjacent two of the plurality of subpixels, the auxiliary electrode electrically connecting the second electrodes of the adjacent two of the plurality of subpixels.

In another aspect, a method for fabricating a display device having a plurality of subpixels including: forming a light emitting diode in each of the plurality of subpixels, the light emitting diode including a first electrode, an emitting layer on the first electrode and a second electrode on the emitting layer; forming a first bank layer surrounding each of the plurality of subpixels on the first electrode; forming an auxiliary electrode on the first bank layer, the auxiliary electrode forming an undercut shape with the first bank layer, the auxiliary electrode contacting the second electrode such that the second electrodes of adjacent two of the plurality of subpixels are electrically connected to each other; and forming a first encapsulation layer on the second electrode of the light emitting diode in each of the plurality of subpixels.

It is to be understood that both the foregoing general description and the following detailed description are by way of example and are intended to provide further explanation of the disclosure.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principles of the disclosure. In the drawings:

FIG. 1 is a view showing a display device according to a first embodiment of the present disclosure;

FIG. 2 is a view showing a subpixel of a display device according to a first embodiment of the present disclosure;

FIG. 3 is a circuit diagram showing a subpixel of a display device according to a first embodiment of the present disclosure;

FIG. 4 is a plan view showing a pixel of a display device according to a first embodiment of the present disclosure;

FIG. 5 is a cross-sectional view, which is taken along a line V-V of FIG. 4, showing a subpixel of a display device according to a first embodiment of the present disclosure;

FIGS. 6A to 6L are cross-sectional views showing a method of fabricating a display device according to a first embodiment of the present disclosure; and

FIG. 7 is a cross-sectional view showing a subpixel of a display device according to a second embodiment of the present disclosure.

### DETAILED DESCRIPTION

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the present disclosure is only defined by scopes of claims.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration may unnecessarily obscure a feature or aspect of the present disclosure, a detailed description of such known function or configuration may be omitted or a brief description may be provided.

Where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or clement may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to distinguish one element from another. For example, a first element could be termed a second clement, and, similarly, a second element could be termed a first element, without departing from the scope of the present disclosure.

The term “at least one” should be understood to include all combinations of one or more of related elements. For example, the term of “at least one of first, second and third elements” may include all combinations of two or more of the first, second and third elements as well as the first, second or third element.

The term “display device” may include a display device in a narrow sense such as liquid crystal module (LCM), an organic light emitting diode (OLED) module and a quantum dot (QD) module including a display panel and a driving unit for driving the display panel. In addition, the term “display device” may include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure may include an applied product or a set device of a final user's device including the LCM, the OLED module and the QD module as well as a display device in a narrow sense such as the LCM, the OLED module and the QD module.

According to circumstances, the LCM, the OLED module and the QD module having a display panel and a driving unit may be expressed as “a display device”, and an electronic apparatus of a complete product including the LCM, the OLED module and the QD module may be expressed as “a set device.” For example, a display device in a narrow sense may include a display panel of a liquid crystal, an organic light emitting diode and a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of a moisture or an oxygen into the emitting element layer. In addition, a layer on the array may include an inorganic light emitting layer, for example, a nano-sized material layer or a quantum dot.

The thin film transistor of the present disclosure may include one of an oxide thin film transistor, an amorphous silicon thin film transistor, a low temperature polycrystalline silicon thin film transistor.

Features of various embodiments of the present disclosure may be partially or entirely coupled to or combined with each other. They may be linked and operated technically in various ways as those skilled in the art can sufficiently understand. The embodiments may be carried out independently of or in association with each other in various combinations.

Hereinafter, a display device according to various example embodiments of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings.

A luminous efficiency of an organic light emitting diode display device is determined by an internal quantum efficiency (IQE) and an external quantum efficiency (EQE). Since the internal quantum efficiency is determined by an emitting material and an internal structure of a display device, the internal quantum efficiency has been improved by development of the emitting material and change of the internal structure.

A light may not be escaped to be confined due to refractive index difference of an interior and an exterior of the display device or a light may be lost due to a surface plasmon polariton. As a result, the external quantum efficiency is determined by a light loss. To improve the external quantum efficiency, a research for minimizing the refractive index difference and an influence of a surface plasmon has been performed.

However, differently from the internal quantum efficiency, it has a limit to improve the external quantum efficiency. The present disclosure is suggested to improve the external quantum efficiency. Specifically, in the present disclosure, the external quantum efficiency is improved by solving a reduction factor of the external quantum efficiency different from the refractive index difference.

In the present disclosure, the luminous efficiency of the display device is improved by changing an arrangement of emitting molecules such as phosphorescent molecules or fluorescent molecules. The luminous efficiency of the display device is improved by changing the arrangement of the emitting molecules in an emitting layer instead of an external condition such as a structure or a refractive index of the display device.

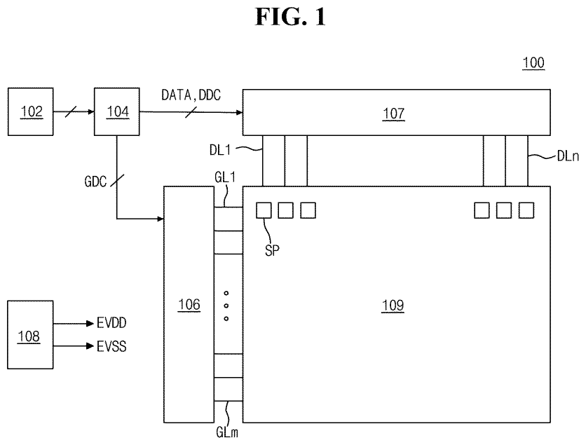

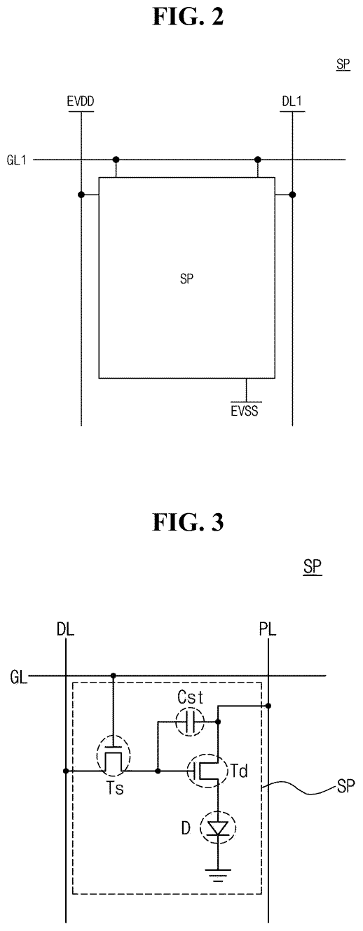

FIG. 1 is a view showing a display device according to a first embodiment of the present disclosure, and FIG. 2 is a view showing a subpixel of a display device according to a first embodiment of the present disclosure.

In FIG. 1, a display device 100 according to a first embodiment of the present disclosure includes an image processing unit 102, a timing controlling unit 104, a gate driving unit 106, a data driving unit 107, a power supplying unit 108 and a display panel 109.

The image processing unit 102 outputs a plurality of timing signals for various units as well as an image signal supplied from an exterior. For example, the plurality of timing signals may include a data enable signal, a vertical synchronization signal, a horizontal synchronization signal and a clock signal.

The timing controlling unit 104 receives the image signal and the plurality of timing signals from the image processing unit 102. The timing controlling unit 104 generates an image data DATA, a gate control signal GDC and a data control signal DDC using the image signal and the plurality of timing signals. The timing controlling unit 104 transmits the gate control signal GDC to the gate driving unit 106 and transmits the image data and the data control signal DDC to the data driving unit 107.

The gate driving unit 106 generates a gate signal (a gate voltage, a scan signal) using the gate control signal GDC transmitted from the timing controlling unit 104 and applies the gate signal to a plurality of gate lines GL1 to GLm of the display panel 109. Although the gate driving unit 106 may be formed as an integrated circuit (IC), it is not limited thereto.

The gate driving unit 106 may have a gate-in-panel (GIP) type where the gate driving unit 106 is disposed on a substrate of the display panel 109.

The data driving unit 107 generates a data signal (a data voltage) using the data control signal DDC and the image data DATA transmitted from the timing controlling unit 104 and applies the data signal to a plurality of data lines DLI to DLn of the display panel 109. The data driving unit 107 samples and latches the image data DATA of a digital type to output the data signal of an analog type based on a gamma reference voltage. Although the data driving unit 107 may be formed as an integrated circuit (IC), it is not limited thereto.

The power supplying unit 108 outputs a high level voltage Vdd and a low level voltage Vss. The power supplying unit 108 supplies the high level voltage Vdd to the display panel 109 through a first power line EVDD and supplies the low level voltage Vss to the display panel 109 through a second power line EVSS. In addition, the high level voltage Vdd and the low level voltage Vss of the power supplying part 108 may be supplied to the gate driving unit 106 or the data driving unit 107 for driving.

The display panel 109 displays an image using the gate signal of the gate driving unit 106, the data signal of the data driving unit 107 and the high level voltage Vdd and the low level voltage Vss of the power supplying unit 108.

The display panel 109 includes a plurality of subpixels SP, a plurality of gate lines GL1 to GLm and a plurality of data lines DL1 to DLn. The plurality of subpixels SP may include red, green and blue subpixels SP or white, red, green and blue subpixels SP. The white, red, green and blue subpixels SP may have the same area as each other or may have a different area from each other.

In FIG. 2, a single subpixel SP may be connected to the gate line GL1, the data line DL1, the first power line EVDD and the second power line EVSS. A driving method as well as a number of a transistor and a capacitor of the subpixel SP may be determined according to a structure of a subpixel circuit. For example, the subpixel SP may have a structure of 2TIC including two transistors and one capacitor. In another embodiment, the subpixel SP may have a structure of one of 3TIC, 4TIC, 5TIC, 6TIC, 7TIC, 3T2C, 4T2C, 5T2C, 6T2C, 7T2C and 8T2C.

FIG. 3 is a circuit diagram showing a subpixel of a display device according to a first embodiment of the present disclosure.

In FIG. 3, the display device 100 includes the gate line GL, the data line DL and the power line PL crossing each other to define the subpixel SP. A switching transistor Ts, a driving transistor Td, a storage capacitor Cst and a light emitting diode D are disposed in the subpixel SP.

The switching transistor Ts is connected to the gate line GL and the data line DL. The driving transistor Td and the storage capacitor Cst are connected between the switching transistor Ts and the power line PL. The light emitting diode D is connected to the driving transistor Td.

When the switching transistor Ts is turned on according to the gate signal of the gate line GL, the data signal of the data line DL is applied to a gate electrode of the driving transistor Td and one capacitor electrode of the storage capacitor Cst through the switching transistor Ts.

Since the driving transistor Td is turned on according to the data signal, a current proportional to the data signal flows from the power line PL to the light emitting diode D through the driving transistor Td and the light emitting diode D emits a light of a luminance proportional to the current flowing through the driving transistor Td.

The storage capacitor Cst is charged up with a voltage proportional to the data signal to keep a voltage of the gate electrode of the driving transistor Td constant for one frame.

Although the subpixel SP includes two transistors Td and Td and one capacitor Cst in an embodiment of FIG. 3, the subpixel SP may include three or more transistors and two or more capacitors in another embodiment.

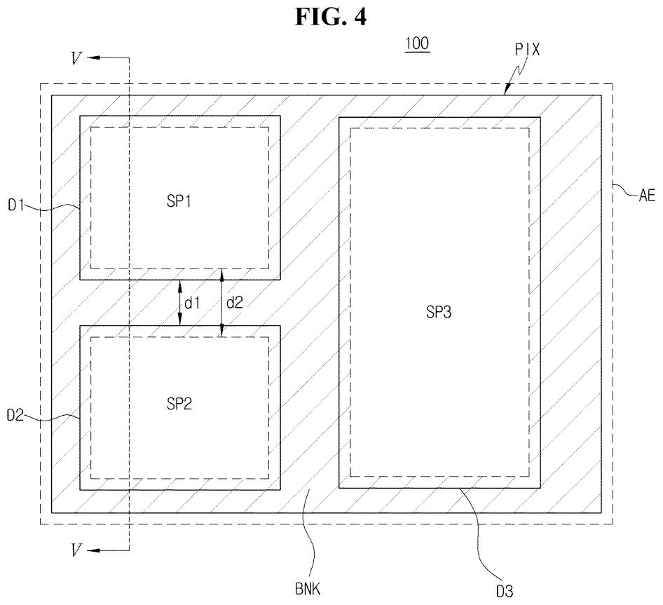

FIG. 4 is a plan view showing a pixel of a display device according to a first embodiment of the present disclosure.

In FIG. 4, the display device 100 may include a plurality of pixels PIX, and each pixel PIX may include a plurality of subpixels SP1, SP2 and SP3. For example, the first, second and third subpixels SP1, SP2 and SP3 may be a green subpixel emitting a green colored light, a red subpixel emitting a red colored light and a blue subpixel emitting a blue colored light, respectively. However, it is not limited thereto. For example, the first subpixel SP1 may be a red subpixel or a blue subpixel, and the second subpixel SP2 may be a green subpixel or a blue subpixel, and the third subpixel SP3 may be a green subpixel or a red subpixel. Further, each pixel PIX may include a white subpixel emitting a white colored light.

Although the plurality of subpixels SP1, SP2 and SP3 have an S-stripe type such that the first and second subpixels SP1 and SP2 are arranged along a vertical direction and the first and second subpixels SP1 and SP2 and the third subpixel SP3 are arranged along a horizontal direction in a first embodiment of FIG. 4, the plurality of subpixels SP1, SP2 and SP3 may have a stripe type, a delta type or a diamond type in another embodiment.

Although an area of the second subpixel SP2 is greater than an area of the first subpixel SP1 and smaller than an area of the third subpixel SP3 in a first embodiment of FIG. 4, the first, second and third subpixels SP1, SP2 and SP3 may have the same area as each other in another embodiment. Further, an area of the second subpixel SP2 may be greater than an area of the third subpixel SP3 and smaller than an area of the first subpixel SP1 in another embodiment. The first, second and third subpixels SP1, SP2 and SP3 may have various areas as necessary in another embodiment.

A bank layer BNK is disposed at a periphery of the first, second and third subpixels SP1, SP2 and SP3. The bank layer BNK surrounds each of the first, second and third subpixels SP1, SP2 and SP3 to define the first, second and third subpixels SP1, SP2 and SP3. The bank layer BNK has openings, and the first, second and third subpixels SP1, SP2 and SP3 are defined by the openings.

First, second and third light emitting diodes D1, D2 and D3 are disposed in the first, second and third subpixels SP1, SP2 and SP3, respectively. For example, the first, second and third light emitting diodes D1, D2 and D3 may be a white light emitting diode emitting a white colored light.

Although not shown, each of the first, second and third light emitting diodes D1, D2 and D3 may include a first electrode, a second electrode and an emitting layer between the first and second electrodes. The first electrode may be an anode. The first electrode is disposed in each of the first, second and third subpixels SP1, SP2 and SP3 and is not electrically connected to the first electrode of the adjacent subpixel. The data signal of the data driving unit 107 may be applied to the first electrode.

The emitting layer may be disposed in each of the first, second and third subpixels SP1, SP2 and SP3 and may be separated from an organic layer of the adjacent subpixel. Although the organic layer is disposed in each of the first, second and third subpixels SP1, SP2 and SP3, the organic layer is divided at a boundary region of the first, second and third subpixels SP1, SP2 and SP3.

The second electrode may be a cathode. The second electrode is disposed in each of the first, second and third subpixels SP1, SP2 and SP3. The low level voltage Vss of the power supplying unit 108 may be supplied to the second electrode.

An auxiliary electrode AE is disposed on the bank layer BNK. A second width d2 of the auxiliary electrode AE is greater than a first width d1 of the bank layer BNK, and the auxiliary electrode AE is electrically connected to the second electrode of the adjacent subpixel. Although the second electrode is disposed in each of the first, second and third subpixels SP1, SP2 and SP3, the second electrode is connected to the auxiliary electrode AE. As a result, the low level voltage Vss of the power supplying unit 108 is applied to the second electrode.

Since the first width d1 between the adjacent subpixels SP1, SP2 and SP3 is minimized, a relatively high resolution is obtained and an aperture ratio of the first, second and third subpixels SP1, SP2 and SP3 increases. In the display device 100, the first width d1 between the adjacent subpixels SP1, SP2 and SP3 is reduced, and a lateral leakage current between the adjacent subpixels SP1, SP2 and SP3 due to reduction of the first width d1 is minimized by blocking a current path between the adjacent subpixels SP1, SP2 and SP3.

Specifically, the organic layer as the path of the lateral current is disposed within each of the first, second and third subpixels SP1, SP2 and SP3 and is not disposed between the adjacent subpixels SP1, SP2 and SP3. As a result, the lateral current between the adjacent subpixels SP1, SP2 and SP3 is blocked, and the lateral leakage current is reduced or minimized.

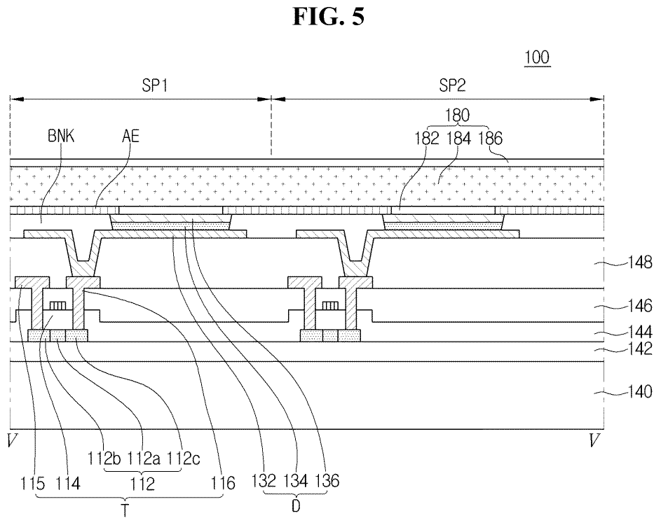

FIG. 5 is a cross-sectional view, which is taken along a line V-V of FIG. 4, showing a subpixel of a display device according to a first embodiment of the present disclosure. Although the display device 100 includes the first, second and third subpixels SP1, SP2 and SP3 displaying different colors, the first, second and third subpixels SP1, SP2 and SP3 have the same structure as each other. As a result, for illustration's convenience, the first and second subpixels SP1 and SP2 are shown in FIG. 5.

In FIG. 5, a buffer layer 142 is disposed on a substrate 140. The substrate 140 may include a hard material such as a glass or a soft material such as a plastic material. When the substrate 140 includes a plastic material, the substrate 140 may include at least one of polyimide (PI), polymethylmethacrylate (PMMA), polyethylene terephthalate (PET), polyether sulfone (PES) and polycarbonate (PC), and it is not limited thereto.

For example, when the substrate 140 includes polyimide, the substrate 140 may include a plurality of polyimide layers. Further, an inorganic layer may be disposed between the polyimide layers, and it is not limited thereto.

The buffer layer 142 may be disposed on the entire substrate 140 to increase an adhesive strength between layers and the substrate 140 and to block an alkali ingredient released from the substrate 140. Further, the buffer layer 142 may delay diffusion of a moisture or an oxygen permeating the substrate 140.

The buffer layer 142 may have a single layer or a multiple layer of an inorganic insulating material such as silicon nitride (SiNₓ) and silicon oxide (SiOₓ). When the buffer layer 142 has a multiple layer, a layer of silicon nitride (SiNₓ) and a layer of and silicon oxide (SiOₓ) may be alternated with each other. The buffer layer 142 may be omitted based on a kind and a material of the substrate 140 and a structure and a type of the thin film transistor.

A thin film transistor T is disposed on the buffer layer 142. Although a driving thin film transistor among a plurality of thin film transistors is shown in FIG. 5, the subpixel may include the other thin film transistor such as a switching thin film transistor. Further, although the thin film transistor T has a top gate structure in FIG. 5, the thin film transistor T may have the other structure such as a bottom gate structure.

The thin film transistor T includes a semiconductor layer 112 on the buffer layer 142, a gate insulating layer 144 on the semiconductor layer 112, a gate electrode 114 on the gate insulating layer 144, an interlayer insulating layer 146 on the gate electrode 114 and source and drain electrodes 115 and 116 on the interlayer insulating layer 146.

The semiconductor layer 112 may include a polycrystalline semiconductor material. For example, the polycrystalline semiconductor material may include polycrystalline silicon, and it is not limited thereto.

The semiconductor layer 112 may include an oxide semiconductor material. For example, the oxide semiconductor material may include one of indium gallium zinc oxide (IGZO), indium zinc oxide (IZO), indium gallium tin oxide (IGTO) and indium gallium oxide (IGO), and it is not limited thereto. The semiconductor layer 112 has a channel region 112a of an intrinsic material at a central portion thereof and source and drain regions 112b and 112c of a doped material at both sides of the channel region 112a.

The gate insulating layer 144 may have a single layer or a multiple layer of an inorganic insulating material such as silicon nitride (SiNₓ) and silicon oxide (SiOₓ), and it is not limited thereto.

The gate electrode 114 includes a metallic material. For example, the gate electrode 114 may have a single layer or a multiple layer of one of molybdenum (Mo), aluminum (Al), chromium (Cr), gold (Au), titanium (Ti), nickel (Ni), neodymium (Nd), copper (Cu) and an alloy thereof, and it is not limited thereto.

The interlayer insulating layer 146 may have a single layer or a multiple layer of an organic insulating material such as photoacryl or an inorganic insulating material such as silicon nitride (SiNₓ) and silicon oxide (SiOₓ). Further, the interlayer insulating layer 146 may have a multiple layer of an organic layer and an inorganic layer, and it is not limited thereto.

The source and drain electrodes 115 and 116 may have a single layer or a multiple layer of one of molybdenum (Mo), aluminum (Al), chromium (Cr), gold (Au), titanium (Ti), nickel (Ni), neodymium (Nd), copper (Cu) and an alloy thereof, and it is not limited thereto. The source and drain electrodes 115 and 116 may be connected to the source and drain regions 112b and 112c, respectively, of the semiconductor layer 112 through contact holes in the gate insulating layer 144 and the interlayer insulating layer 146.

Although not shown, a bottom shielding metal layer may be disposed on the substrate 140 under the semiconductor layer 112. The bottom shielding metal layer may minimize a back channel phenomenon generated due to charges trapped in the substrate 140 to prevent a residual image or deterioration of a transistor. The bottom shielding metal layer may have a single layer or a multiple layer of one of titanium (Ti), molybdenum (Mo) and an alloy thereof, and it is not limited thereto.

A planarizing layer 148 is disposed on the thin film transistor T over the entire substrate 140. The planarizing layer 148 may include an organic insulating material such as photoacryl, and it is not limited thereto. The planarizing layer 148 may have a multiple layer of an inorganic layer and an organic layer.

A light emitting diode D is disposed on the planarizing layer 148. The light emitting diode D includes a first electrode 132, an emitting layer 134 and a second electrode 136.

The first electrode 132 may be an anode. The first electrode 132 is disposed on the planarizing layer 148 and is electrically connected to the drain electrode 116 of the thin film transistor T through a contact hole in the planarizing layer 148. The first electrode 132 may include at least one of silver (Ag), aluminum (Al), gold (Au), molybdenum (Mo), tungsten (W), chromium (Cr) and an alloy thereof. Alternatively, the first electrode 132 may include a transparent conductive material such as indium tin oxide (ITO) and indium zinc oxide (IZO).

When the display device 100 has a top emission type, the first electrode 132 may further include an opaque conductive material for using the first electrode 132 as a reflective layer. When the display device 100 has a bottom emission type, the first electrode 132 may include a transparent conductive material such as indium tin oxide (ITO) and indium zinc oxide (IZO).

The bank layer BNK is disposed in a boundary region of each subpixel. The bank layer BNK may be a kind of wall defining each of the first and second subpixels SP1 and SP2. The bank layer BNK may prevent a mixture of lights of various colors emitted from adjacent subpixels SP1 and SP2.

The bank layer BNK surrounds each of the first and second subpixels SP1 and SP2, and has an opening exposing the first electrode 132 in each of the first and second subpixels SP1 and SP2. The bank layer BNK may include at least one of an inorganic insulating material such as silicon nitride (SiNₓ) and silicon oxide (SiOₓ).

The auxiliary electrode AE is disposed on the bank layer BNK. The auxiliary electrode AE may include at least one of silver (Ag), aluminum (Al), gold (Au), molybdenum (Mo), tungsten (W), chromium (Cr) and an alloy thereof.

A width of the auxiliary electrode AE may be greater than a width of the bank layer BNK such that the bank layer BNK and the auxiliary electrode AE have an undercut shape or an overhang shape. As a result, the auxiliary electrode AE protrudes from an upper edge portion of the bank layer BNK along a horizontal direction by a predetermined distance.

The emitting layer 134 is disposed on a top surface of the first electrode 132 exposed through the opening of the bank layer BNK. The emitting layer 134 is disposed only within the opening of the bank layer BNK and is not disposed on a top surface of the bank layer BNK.

The emitting layer 134 includes an organic emitting material. Alternatively, the emitting layer 134 may include an inorganic emitting material. For example, the emitting layer 134 may be a nano-sized material layer, a quantum dot layer, a micro light emitting diode layer or a mini light emitting diode layer, and it is not limited thereto.

When the emitting layer 134 includes an organic emitting material, the emitting layer 134 may have a blue organic emitting layer and a yellow organic emitting layer and may emit a white colored light. Alternatively, the emitting layer 134 may have a multiple stack structure. For example, when the emitting layer 134 has a triple stack structure, the emitting layer 134 may have first, second and third stacks and first and second charge generating layers between the first and second stacks and between the second and third stacks. Each of the first, second and third stacks may include an emitting material layer, an electron injecting layer injecting an electron, a hole injecting layer injecting a hole, an electron transporting layer transporting an electron, and a hole transporting layer transporting a hole. For example, the emitting material layers of the first, second and third stacks may emit a red colored light, a blue colored light and a green colored light, respectively.

The second electrode 136 is disposed on the emitting layer 134. The second electrode 136 is disposed only within the opening of the bank layer BNK and is not disposed on the top surface of the bank layer BNK. Specifically, the top surface of the second electrode 136 is flush with the top surface of the bank layer BNK such that the top surface of the second electrode 136 and the top surface of the bank layer BNK form a flat surface. As a result, a portion of the auxiliary electrode AE protruding from the upper edge portion of the bank layer BNK is disposed on the top surface of the second electrode 136 to electrically contact the second electrode 136.

Since the auxiliary electrode AE and the second electrode 136 are electrically connected to each other, the second electrode 136 functions as a common layer to simultaneously apply the low level voltage Vss to the second electrode 136 through the entire display device 100.

When the display device 100 has a top emission type, the second electrode 136 may include a half transmissive conductive material transmitting a light. For example, the second electrode 136 may include at least one of alloys of LiF/Al, CsF/Al, Mg:Ag, Ca/Ag, Ca:Ag, LiF/Mg:Ag, LiF/Ca/Ag and LiF/Ca:Ag.

When the display device 100 has a bottom emission type, the second electrode 136 may include an opaque conductive material for using the second electrode 136 as a reflective layer. For example, the second electrode 136 may include at least one of silver (Ag), aluminum (Al), gold (Au), molybdenum (Mo), tungsten (W), chromium (Cr) and an alloy thereof.

An encapsulating layer 180 is disposed on the light emitting diode D to encapsulate the light emitting diode D. When the light emitting diode D is exposed to a moisture or an oxygen, a pixel shrinkage phenomenon where an emission area is reduced or deterioration of a dark spot in the emission area may occur. Further, a moisture or an oxygen may oxidize the electrode of a metallic material. The encapsulating layer 180 blocks permeation of a moisture or an oxygen from an exterior to prevent deterioration of the light emitting diode D and the electrodes.

Although the encapsulating layer 180 has a triple layer of first, second and third encapsulating layers 182, 184 and 186 in a first embodiment, the encapsulating layer 180 may have a double layer or a quadruple layer in another embodiment.

The first encapsulating layer 182 is disposed in each of the first and second subpixels SP1 and SP2. While the second and third encapsulating layers 184 and 186 are disposed on the entire substrate 140, the first encapsulating layer 182 is disposed in the corresponding subpixel SP1 and SP2. Although a top surface of the first encapsulating layer 182 is flush with the top surface of the auxiliary electrode AE in FIG. 5, it is not limited thereto.

The first and third encapsulating layer 182 and 186 may have a single layer or a multiple layer of an inorganic material such as silicon oxide (SiOₓ), silicon oxynitride (SiON) and silicon nitride (SiNₓ), and it is not limited thereto. The first and third encapsulating layer 182 and 186 may further include an organic material between the inorganic materials, and it is not limited thereto. The second encapsulating layer 184 may include an organic material such as epoxy resin, polyimide, polyethylene and silicon oxycarbide (SiOC), and it is not limited thereto. Although the third encapsulating layer 186 may include a face seal metal, it is not limited thereto.

Although not shown, the display device 100 may include a touch unit. The touch unit may be disposed in the display area to sense a touch input. For example, the touch unit may sense an external touch information using a finger of a user or a touch pen.

In the display device 100 according to a first embodiment of the present disclosure, since the light emitting diode D is disposed in each of the first, second and third subpixels SP1, SP2 and SP3, the emitting layer 134 is separated between the adjacent subpixels SP1, SP2 and SP3. As a result, the path of the lateral current between the adjacent subpixels SP1, SP2 and SP3 is removed, and the lateral leakage current between the adjacent subpixels SP1, SP2 and SP3 is prevented.

Further, since the first encapsulating layer 182 is disposed within each subpixel SP1, SP2 and SP3 instead of the entire substrate 140, deterioration of elements such as the light emitting diode D in one subpixel (e.g., the first subpixel SP1) due to chemicals of a photolithographic process for another subpixel (e.g., the second subpixel SP2) is prevented.

A method of fabricating the display device 100 will be illustrated hereinafter.

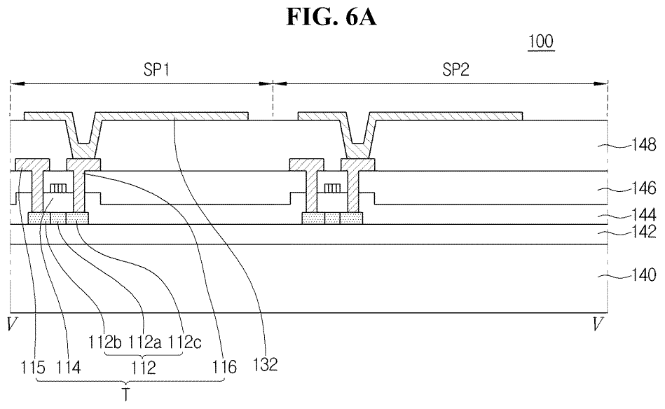

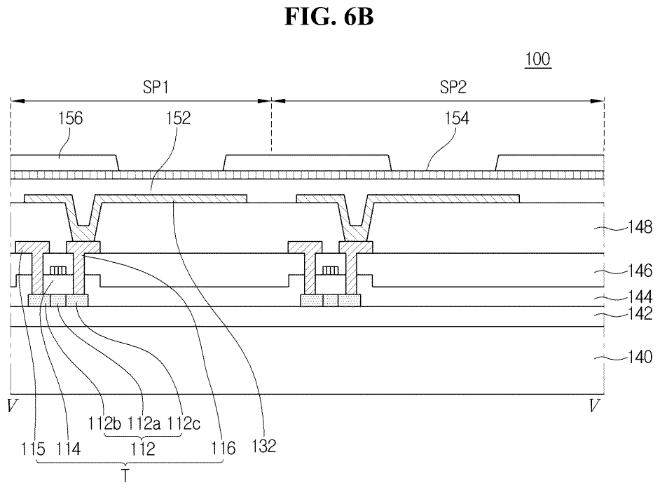

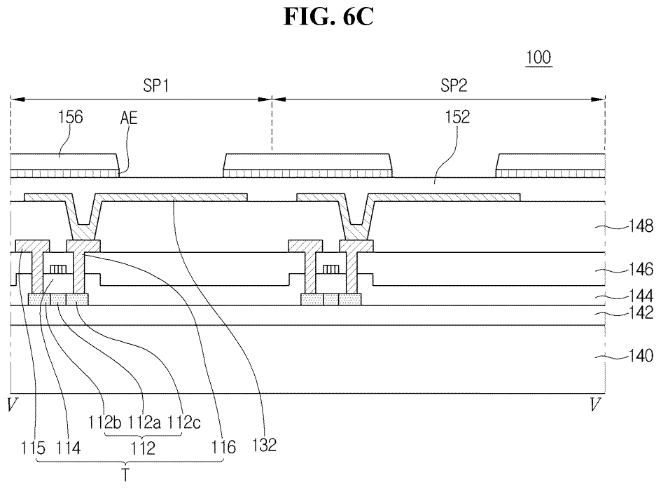

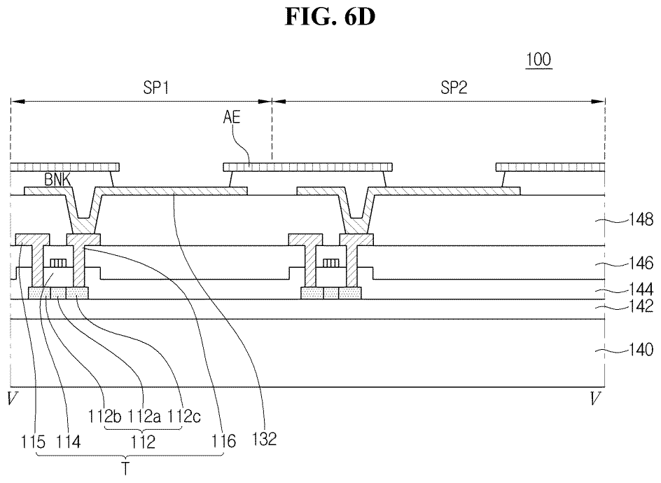

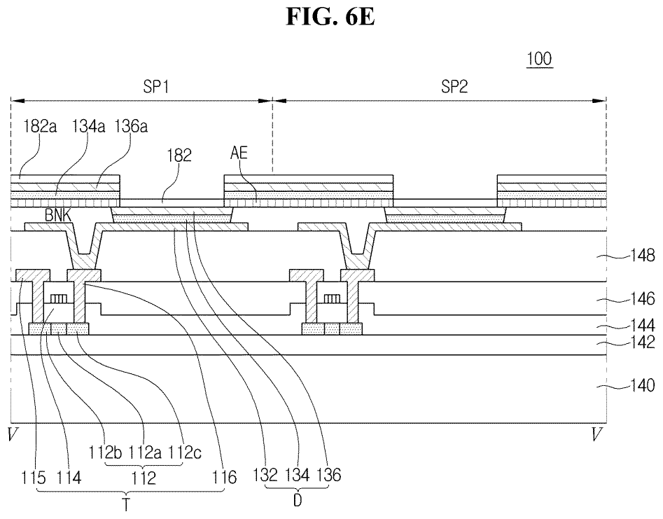

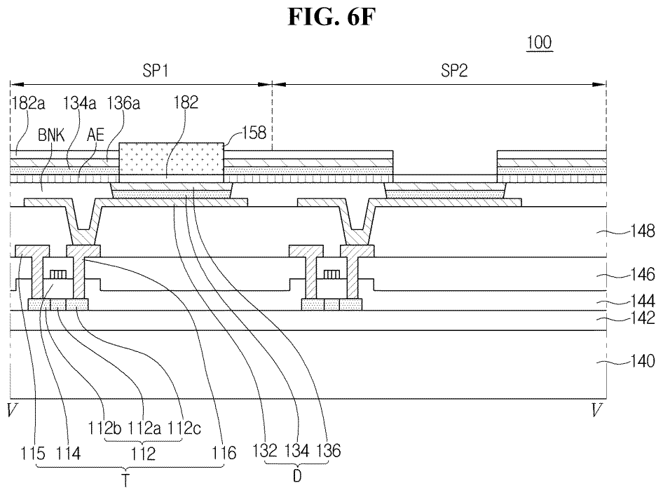

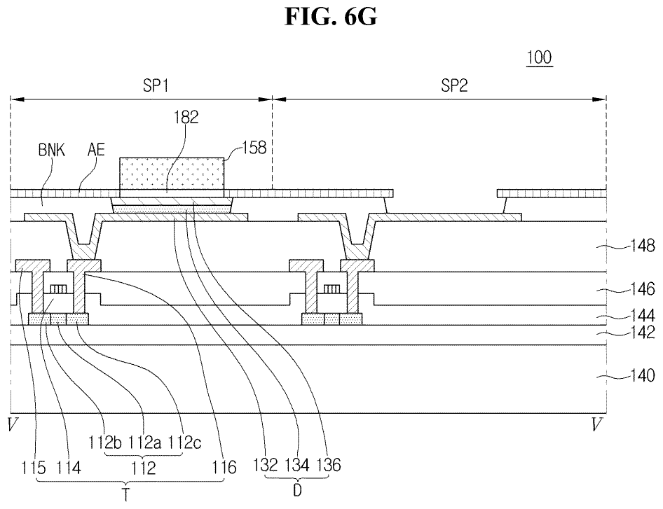

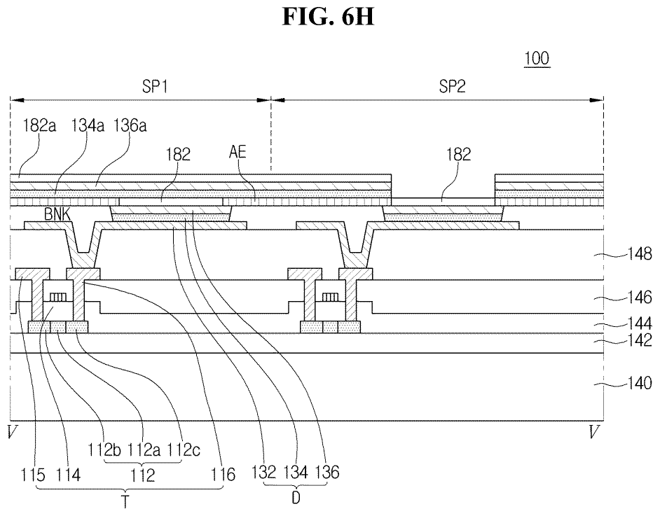

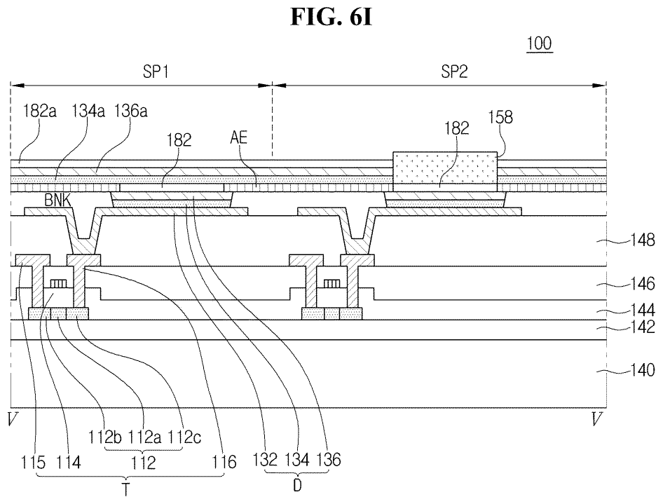

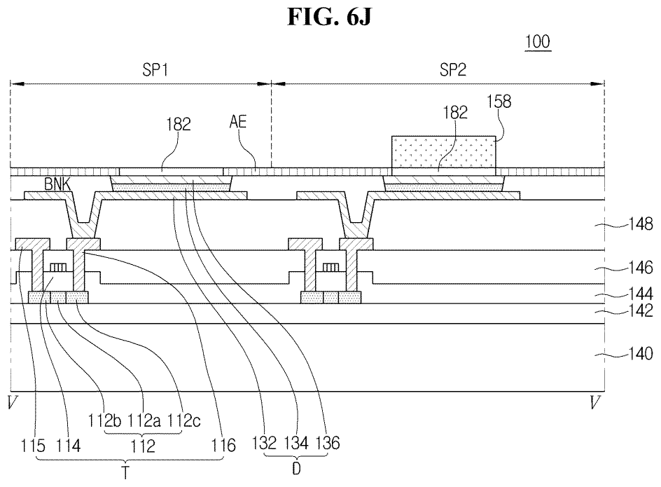

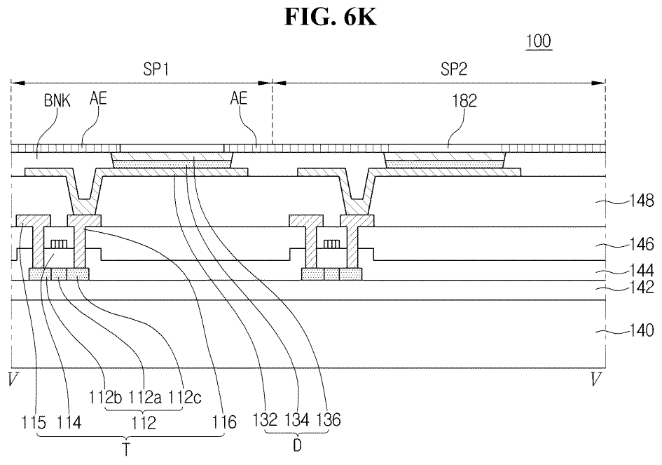

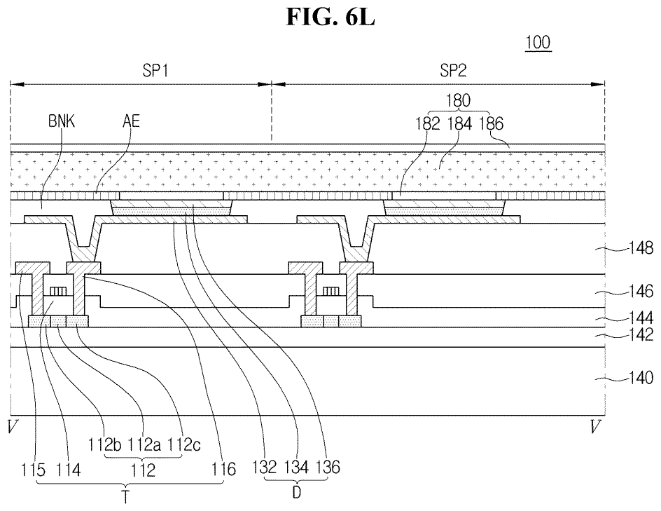

FIGS. 6A to 6L are cross-sectional views showing a method of fabricating a display device according to a first embodiment of the present disclosure.

In FIG. 6A, the buffer layer 142 is formed on the entire substrate 140 including the first and second subpixels SP1 and SP2.

The substrate 140 may include a hard material such as a glass or a soft material such as a plastic material. The plastic material may include at least one of polyimide (PI), polymethylmethacrylate (PMMA), polyethylene terephthalate (PET), polyether sulfone (PES) and polycarbonate (PC).

The buffer layer 142 may have a single layer or a multiple layer of an inorganic insulating material such as silicon nitride (SiNx) and silicon oxide (SiOx).

Next, the semiconductor layer 112 is formed on the buffer layer 142 in each of the first and second subpixels SP1 and SP2 by depositing and patterning a polycrystalline semiconductor material such as polycrystalline silicon or an oxide semiconductor material such as indium gallium zinc oxide (IGZO), indium zinc oxide (IZO), indium gallium tin oxide (IGTO) and indium gallium oxide (IGO). In addition, the channel region 112a, the source region 112b and the drain region 112c by doping side portions of the semiconductor layer 112 with an impurity.

Next, the gate insulating layer 144 is formed on the semiconductor layer 112 by depositing an inorganic insulating material such as silicon nitride (SiNx) and silicon oxide (SiOx).

Next, the gate electrode 114 is formed on the gate insulating layer 144 over the semiconductor layer 112 in each of the first and second subpixels SP1 and SP2 by depositing and patterning a metallic material such as molybdenum (Mo), aluminum (Al), chromium (Cr), gold (Au), titanium (Ti), nickel (Ni), neodymium (Nd), copper (Cu) and an alloy thereof.

Next, the interlayer insulating layer 146 is formed on the gate electrode 114 by depositing an organic insulating material such as photoacryl or an inorganic insulating material such as silicon nitride (SiNx) and silicon oxide (SiOx). Next, the contact holes are formed in the interlayer insulating layer 146 and the gate insulating layer 144 exposing the source and drain regions 112b and 112c of the semiconductor layer 112 by patterning the interlayer insulating layer 146 and the gate insulating layer 144.

Next, the source and drain electrodes 115 and 116 are formed on the interlayer insulating layer 146 over the semiconductor layer 112 by depositing and patterning a metallic material such as molybdenum (Mo), aluminum (Al), chromium (Cr), gold (Au), titanium (Ti), nickel (Ni), neodymium (Nd), copper (Cu) and an alloy thereof. The source and drain electrodes 115 and 116 are connected to the source and drain regions 112b and 112c, respectively, of the semiconductor layer 112 through the contact holes in the gate insulating layer 144 and the interlayer insulating layer 146.

Next, the planarizing layer 148 is formed on the source and drain electrodes 115 and 116 by depositing an organic insulating material such as photoacryl. The planarizing layer 148 has the contact hole exposing the drain electrode 116.

Next, the first electrode 132 is formed on the planarizing layer 148 in each of the first and second subpixels SP1 and SP2 by depositing and patterning a metallic material such as silver (Ag), aluminum (Al), gold (Au), molybdenum (Mo), tungsten (W), chromium (Cr) and an alloy thereof or a transparent conductive material such as indium tin oxide (ITO) and indium zinc oxide (IZO). The first electrode 132 is electrically connected to the drain electrode 116 through the contact hole in the planarizing layer 148.

In FIG. 6B, an inorganic material layer 152 is formed on the first electrode 132 over the entire substrate 140 by depositing an inorganic material such as silicon oxide (SiOx) and silicon nitride (SiNx).

Next, a metallic material layer 154 is formed on the inorganic material layer 152 by depositing a metallic material such as at least one of silver (Ag), aluminum (Al), gold (Au), molybdenum (Mo), tungsten (W), chromium (Cr) and an alloy thereof.

Next, a first photoresist pattern 156 is formed on the metallic material layer 154 by coating, exposing and developing a photoresist over the entire substrate 140. The first photoresist pattern 156 may be disposed in a boundary portion of each of the first and second subpixels SP1 and SP2.

In FIG. 6C, the auxiliary electrode AE is formed on the inorganic material layer 152 by patterning the metallic material layer 154 using the first photoresist pattern as an etching mask.

In FIG. 6D, the bank layer BNK is formed on the first electrode 132 by patterning the inorganic material layer 154 using the first photoresist pattern 156 and the auxiliary electrode AE. The inorganic material layer 154 may be patterned through a dry etching method using an etching gas. Since the dry etching method has an isotropic property, a portion of the inorganic material layer 152 under the auxiliary electrode AE is etched. As a result, the width of the bank layer BNK is smaller than the width of the auxiliary electrode AE such that the bank layer BNK and the auxiliary electrode AE have an undercut shape or an overhang shape.

In FIG. 6E, the emitting layer 134, the second electrode 136 and the first encapsulating layer 182 are formed on the first electrode 132 in the first and second subpixels SP1 and SP2 between the bank layers BNK and an emitting material pattern 134a, a metallic material pattern 136a and an insulating material pattern 182a are formed on the auxiliary electrode AE by sequentially depositing an emitting material, a metallic material and an inorganic insulating material. The metallic material may include one of alloys of LiF/Al, CsF/Al, Mg:Ag, Ca/Ag, Ca:Ag, LiF/Mg:Ag, LiF/Ca/Ag and LiF/Ca:Ag or one of silver (Ag), aluminum (Al), gold (Au), molybdenum (Mo), tungsten (W), chromium (Cr) and an alloy thereof, and the inorganic insulating material may include one of silicon oxide (SiOₓ), silicon oxynitride (SiON) and silicon nitride (SiNₓ).

The emitting material may include one of red, green and blue emitting materials.

The top surface of the second electrode 136 in the first subpixel SP1 may be flush with the top surface of the bank layer BNK in the first subpixel SP1 such that the top surface of the second electrode 136 is electrically connected to the bottom surface of the auxiliary electrode AE of an undercut shape. The top surface of the first encapsulating layer 182 in the first subpixel SP1 may be flush with the top surface of the auxiliary electrode AE in the first subpixel SP1.

In FIG. 6F, a second photoresist pattern 158 is formed on the first encapsulating layer 182 in the first subpixel SP1 by coating, exposing and developing a photoresist over the entire substrate 140.

In FIG. 6G, the emitting material pattern 134a, the metallic material pattern 136a and the insulating material pattern 182a on the auxiliary electrode AE and the emitting layer 134, the second electrode 136 and the first encapsulating layer 182 on the first electrode 132 in the second subpixel SP2 are removed using the second photoresist pattern 158 as an etching mask. As a result, the light emitting diode D including the first electrode 132, the emitting layer 134 and the second electrode 136 and the first encapsulating layer 182 are formed in the first subpixel SP1.

In FIG. 6H, the second photoresist pattern 158 in the first subpixel SP1 is removed.

Next, the emitting layer 134, the second electrode 136 and the first encapsulating layer 182 are formed on the first electrode 132 in the second subpixel SP2 between the bank layers BNK and an emitting material pattern 134a, a metallic material pattern 136a and an insulating material pattern 182a are formed on the auxiliary electrode AE by sequentially depositing an emitting material, a metallic material and an inorganic insulating material. The metallic material may include one of alloys of LiF/Al, CsF/Al, Mg:Ag, Ca/Ag, Ca:Ag, LiF/Mg:Ag, LiF/Ca/Ag and LiF/Ca:Ag or one of silver (Ag), aluminum (Al), gold (Au), molybdenum (Mo), tungsten (W), chromium (Cr) and an alloy thereof, and the inorganic insulating material may include one of silicon oxide (SiOx), silicon oxynitride (SiON) and silicon nitride (SiNx).

The emitting material may include the other one of red, green and blue emitting materials.

The top surface of the second electrode 136 in the second subpixel SP2 may be flush with the top surface of the bank layer BNK in the second subpixel SP2 such that the top surface of the second electrode 136 is electrically connected to the bottom surface of the auxiliary electrode AE of an undercut shape. The top surface of the first encapsulating layer 182 in the second subpixel SP2 may be flush with the top surface of the auxiliary electrode AE in the second subpixel SP2.

In FIG. 6I, a second photoresist pattern 158 is formed on the first encapsulating layer 182 in the second subpixel SP2 by coating, exposing and developing a photoresist over the entire substrate 140.

In FIG. 6J, the emitting material pattern 134a, the metallic material pattern 136a and the insulating material pattern 182a on the auxiliary electrode AE are removed using the second photoresist pattern 158 as an etching mask. As a result, the light emitting diode D including the first electrode 132, the emitting layer 134 and the second electrode 136 and the first encapsulating layer 182 are formed in the second subpixel SP2.

In FIG. 6K, the second photoresist pattern 158 in the second subpixel SP2 is removed.

Although not shown, the steps of FIGS. 6E to 6G or FIGS. 6H to 6J may be performed to the third subpixel SP3, and the light emitting diode D including the first electrode 132, the emitting layer 134 and the second electrode 136 and the first encapsulating layer 182 are formed in the third subpixel SP3.

For example, when the display device 100 includes three subpixels corresponding to red, green and blue colors, the steps of FIGS. 6E to 6G or FIGS. 6H to 6J may be performed three times to form the light emitting diode D and the first encapsulating layer 182 in all subpixels.

In FIG. 6L, the second encapsulating layer 184 is formed on the auxiliary electrode AE and the first encapsulating layer 182 by depositing an organic material over the entire substrate 140, and the third encapsulating layer 186 is formed on the second encapsulating layer 182 by depositing an inorganic material over the entire substrate 140. As a result, the display device 100 encapsulated with the encapsulating layer 180 is obtained.

In the display device 100 according to a first embodiment of the present disclosure, after the auxiliary electrode AE is formed on the bank layer BNK of an inorganic material, the emitting layer 134, the second electrode 136 and the first encapsulating layer 182 are formed using the bank layer BNK and the auxiliary electrode AE having an undercut shape or an overhang shape without an additional mask process. As a result, a fabrication process of the display device 100 is simplified.

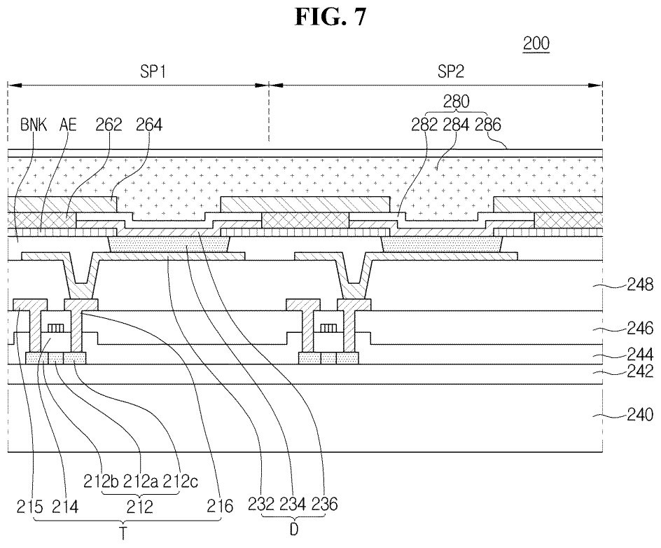

FIG. 7 is a cross-sectional view showing a subpixel of a display device according to a second embodiment of the present disclosure. An illustration on the same part as that of the first embodiment will be omitted.

In FIG. 7, a thin film transistor T and a light emitting diode D are disposed in each of first and second subpixels SP1 and SP2 on a substrate 240.

The thin film transistor T includes a semiconductor layer 212 on a buffer layer 242, a gate insulating layer 244 on the semiconductor layer 212, a gate electrode 214 on the gate insulating layer 244, an interlayer insulating layer 246 on the gate electrode 214 and source and drain electrodes 215 and 216 on the interlayer insulating layer 246.

A bank layer BNK is disposed in a boundary region of each of the first and second subpixels SP1 and SP2, and the light emitting diode D is disposed in each of the first and second subpixels SP1 and SP2 defined by the bank layer BNK. The bank layer BNK may include at least one of an inorganic insulating material such as silicon nitride (SiNx) and silicon oxide (SiOx), and it is not limited thereto.

The light emitting diode D includes a first electrode 232, an emitting layer 234 and a second electrode 236. The first electrode 232 may be an anode, and the second electrode 236 may be a cathode.

An auxiliary electrode AE of a conductive metallic material is disposed on the bank layer BNK, and first and second patterns 262 and 264 are disposed on the auxiliary electrode AE. The first and second patterns 262 and 264 may include materials having different etch rates, and the first and second patterns 262 and 264 may be formed to have an undercut shape or an overhang shape due to the different etch rates. For example, the first pattern 262 may include an inorganic material such as silicon oxide (SiOx) and silicon nitride (SiNx), and the second pattern 264 may include an amorphous material such as amorphous silicon. However, it is not limited thereto.

Since the first and second patterns 262 and 264 are disposed on the bank layer BNK, the first and second patterns 262 and 264 also define the first and second subpixels SP1 and SP2.

A first encapsulating layer 282 is disposed in each of the first and second subpixels SP1 and SP2 surrounded by the first and second patterns 262 and 264. The first encapsulating layer 282 is formed to be separated in each of the first and second subpixels SP1 and SP2. Although a top surface of the first encapsulating layer 282 is flush with the top surface of the first pattern 262 such that the top surface of the first encapsulating layer 282 contacts the bottom surface of the second pattern 264 having an undercut shape in FIG. 7, it is not limited thereto.

Since the first and second patterns 262 and 264 define the first and second subpixels SP1 and SP2, the first and second patterns 262 and 264 may be regarded as another bank layer having an undercut shape or an overhang shape.

In a display device 200 according to a second embodiment of the present disclosure, a double layered bank layer is disposed between the first and second subpixels SP1 and SP2, and the auxiliary electrode AE is disposed between the double layered bank layer. Although the light emitting diode D and the first encapsulating layer 282 are disposed in each of the first and second subpixels SP1 and SP2 defined by the double layered bank layer, the second electrodes 236 of all subpixels SP1 and SP2 are electrically connected to each other through the auxiliary electrode AE. As a result, all of the second electrodes 236 function as a common electrode.

A second encapsulating layer 284 of an organic material and a third encapsulating layer 286 of an inorganic material are disposed on the second pattern 264 and the first encapsulating layer 282 over the entire substrate 240.

In the display device 200 according to a second embodiment of the present disclosure, since the light emitting diode D is disposed in each of the first and second subpixels SP1 and SP2, the emitting layer 234 is cut (is separated, is not connected) between the adjacent subpixels SP1 and SP2. As a result, the path of the lateral current between the adjacent subpixels SP1 and SP2 is removed, and the lateral leakage current between the adjacent subpixels SP1 and SP2 is prevented.

Further, since the first encapsulating layer 282 is not disposed over the entire substrate 240 but disposed in each subpixel SP1 and SP2, deterioration of elements such as the light emitting diode D in one subpixel (e.g., the first subpixel SP1) due to chemicals of a photolithographic process for another subpixel (e.g., the second subpixel SP2) is prevented.

In the display device 100 according to a first embodiment of the present disclosure of FIG. 5, since the auxiliary electrode AE and the bank layer BNK have an undercut shape or an overhang shape, the emitting layer 134 and the second electrode 136 may be formed without an additional mask process. In the display device 200 according to a second embodiment of the present disclosure of FIG. 7, an additional bank layer of the first and second patterns 262 and 264 having an undercut shape or an overhang shape is formed on the bank layer BNK, and the emitting layer 234 and the second electrode 236 are formed without an additional mask process. As a result, the fabrication process is simplified and the fabrication cost is reduced.

Consequently, in the display device 100 and 200 according to the present disclosure, since the emitting layer is disposed in each subpixel, the emitting layer is cut between the adjacent subpixels. As a result, the path of the lateral current is removed, and the lateral leakage current between the adjacent subpixels is prevented.

Further, the auxiliary electrode is disposed on the bank layer and is electrically connected to the second electrode of the corresponding subpixel. Since the low level voltage is applied to the second electrode through the auxiliary electrode, the signal delay or the voltage drop due to the resistance of the second electrode is prevented.

In addition, since the bank layer and the auxiliary electrode have an undercut shape, the emitting layer and the second electrode are formed without an additional mask process. As a result, the fabrication process is simplified and the fabrication cost is reduced.

Moreover, since the display device having a high efficiency and a high luminance is obtained by reducing the lateral leakage current, the power consumption is reduced.

It will be apparent to those skilled in the art that various modifications and variation can be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A display device comprising:
a substrate having a plurality of subpixels;
a transistor in each of the plurality of subpixels;
a first bank layer surrounding the plurality of subpixels;
an auxiliary electrode on the first bank layer;
a light emitting diode in each of the plurality of subpixels, the light emitting diode including a first electrode, an emitting layer on the first electrode and a second electrode on the emitting layer; and
a first encapsulating layer on the light emitting diode in each of the plurality of subpixels,
wherein the auxiliary electrode and the first bank layer have an undercut shape, and
wherein the second electrode contacts the auxiliary electrode such that the second electrodes of adjacent two of the plurality of subpixels are electrically connected to each other.

2. The display device of claim 1, wherein the emitting layer and the second electrode are disposed in a region surrounded by the first bank layer.

3. The display device of claim 2, wherein a top surface of the second electrode is flush with a top surface of the first bank layer such that the top surface of the second electrode contacts a bottom surface of the auxiliary electrode.

4. The display device of claim 2, wherein a top surface of the first encapsulating layer is flush with a top surface of the auxiliary electrode.

5. The display device of claim 1, wherein the first bank layer includes an inorganic material.

6. The display device of claim 1, further comprising a second bank layer on the auxiliary electrode.

7. The display device of claim 6, wherein the second bank layer comprises:
a first pattern on the auxiliary electrode; and
a second pattern on the first pattern.

8. The display device of claim 7, wherein the first pattern and the second pattern have an undercut shape.

9. The display device of claim 8, wherein a top surface of the emitting layer is flush with a top surface of the first bank layer, and
wherein the second electrode and the first encapsulating layer are disposed in a region surrounded by the second bank layer.

10. The display device of claim 9, wherein the second electrode extends toward a top surface of the auxiliary electrode to electrically contact the auxiliary electrode.

11. The display device of claim 9, wherein a top surface of the first encapsulating layer contacts a bottom surface of the second pattern.

12. The display device of claim 7, wherein the first and second patterns have material having different etch rates.

13. The display device of claim 12, wherein the first pattern includes an inorganic material and the second pattern includes an amorphous material.

14. The display device of claim 1, further comprising:
a second encapsulating layer of an organic material over the substrate; and
a third encapsulating layer of an inorganic material on the second encapsulating layer.

15. A display device comprising:
a substrate having a plurality of subpixels;
a bank layer surrounding the plurality of subpixels;
a light emitting diode in each of the plurality of subpixels, the light emitting diode including a first electrode, an emitting layer on the first electrode and a second electrode on the emitting layer;
a first encapsulating layer in each of the plurality of subpixels; and
an auxiliary electrode between adjacent two of the plurality of subpixels, the auxiliary electrode electrically connecting the second electrodes of the adjacent two of the plurality of subpixels.

16. The display device of claim 15, wherein the bank layer and the auxiliary electrode have an undercut shape.

17. The display device of claim 16, wherein a top surface of the second electrode electrically contacts a bottom surface of the auxiliary electrode.

18. The display device of claim 15, wherein the bank layer includes a first pattern and a second pattern on the first pattern and has an undercut shape on the auxiliary electrode,
wherein a bottom surface of the second electrode electrically contacts a top surface of the auxiliary electrode.

19. A method for fabricating a display device having a plurality of subpixels, comprising:
forming a light emitting diode in each of the plurality of subpixels, the light emitting diode including a first electrode, an emitting layer on the first electrode and a second electrode on the emitting layer;
forming a first bank layer surrounding each of the plurality of subpixels on the first electrode;
forming an auxiliary electrode on the first bank layer, the auxiliary electrode forming an undercut shape with the first bank layer, the auxiliary electrode contacting the second electrode such that the second electrodes of adjacent two of the plurality of subpixels are electrically connected to each other; and
forming a first encapsulation layer on the second electrode of the light emitting diode in each of the plurality of subpixels.

20. The method of claim 19, further comprising
forming a second bank layer on the auxiliary electrode, the second bank layer including a first pattern and a second pattern on the first pattern, the first and second patterns having an undercut shape.
